(19) United States
(12) Patent Application Publication
(10) Pub. No.: US 2026/0011609 A1
(43) Pub. Date: Jan. 8, 2026

(54) METHOD FOR MEASURING THICKNESS OF A SUBSTRATE

(71) Applicant: Samsung Electronics Co., Ltd., Suwon-si (KR)

(72) Inventors: Sungho JANG, Suwon-si (KR); Jinoh IM, Suwon-si (KR); Bumsub SONG, Suwon-si (KR); Yumi YANG, Suwon-si (KR); Wonguk SEO, Suwon-si (KR); Sungwon CHO, Suwon-si (KR); Jungryul LEE, Suwon-si (KR)

(21) Appl. No.: 18/983,524

(22) Filed: Dec. 17, 2024

(30) Foreign Application Priority Data
Jul. 3, 2024 (KR) 10-2024-0087834

(51) Int. Cl. H01L 21/66; G01B 11/06

(52) U.S. Cl. CPC H01L 22/12; G01B 11/06

(57) ABSTRACT

A method for measuring a thickness of a substrate for a workpiece including the substrate having a first side and a second side disposed in a direction opposite to the first side may be performed by a computing device and may include receiving, from a first measurement device, first side profile information including total surface position information of the first side, receiving, from a second measurement device, a plurality of pieces of substrate sample thickness information indicating sample thicknesses of the substrate measured at a plurality of sampling points on the first side, and generating, based on the first side profile information and the plurality of pieces of substrate sample thickness information, a substrate thickness map including total thickness information of the substrate.

### CROSS-REFERENCE TO RELATED APPLICATION

This application claims priority under 35 U.S.C. § 119 to Korean Patent Application No. 10-2024-0087834, filed in the Korean Intellectual Property Office on Jul. 3, 2024, the entire contents of which are hereby incorporated by reference.

### BACKGROUND

### Technical Field

The present disclosure relates to a method for measuring a thickness of a substrate.

### Description of Related Art

Manufacturing a semiconductor device involves performing a series of unit processes including etching, ashing, ion implantation, thin film deposition, cleaning, etc. Among these unit processes, etching may be performed using a plasma processing device that induces a plasma reaction. In addition, for the planarization process using a semiconductor processing device such as a plasma processing device, it may be required to measure the exact thickness of the substrate to improve the target etching thickness or target flatness.

Meanwhile, an active region for performing a function of an integrated circuit may be included on a front side of the semiconductor substrate. Accordingly, power wiring and signal wiring may be connected to the front side of the semiconductor substrate to supply power and transmit signals from the package to the active region of the semiconductor substrate. Meanwhile, demands for miniaturization, high capacity, etc. require higher integration of semiconductors, and to this end, back-side power delivery network (BSPDN) is used, which includes a power wiring structure to distribute power on a back side opposite to the front side where the signal wiring structure is placed, so as to reduce congestion in supplying power and transmit signals to the front side of the semiconductor substrate. It may be necessary to remove or planarize the back bonding layer of the semiconductor substrate to form the BSPDN on the semiconductor substrate. However, it may be difficult to measure the exact thickness of the substrate if the back planarization process of the semiconductor substrate is performed, because the front side on which the signal wiring structure is placed is not exposed to the outside.

The information described above is intended to improve understanding of the background of the present disclosure, and may include information that does not constitute the related art.

### SUMMARY

In order to solve one or more problems (e.g., the problems described above and/or other problems not explicitly described herein), the present disclosure provides a method for measuring a thickness of a substrate.

In order to solve one or more problems (e.g., the problems described above and/or other problems not explicitly described herein), the present disclosure provides a method for manufacturing a semiconductor device with improved integration density.

The objects to be achieved by the present disclosure are not limited to the above, and other objects not explicitly described herein may be clearly understood by those skilled in the art from the description of the present disclosure.

According to an aspect, a method for measuring a thickness of a substrate for a workpiece including the substrate having a first side and a second side disposed in a direction opposite to the first side may be performed by a computing device and may include receiving, from a first measurement device, first side profile information including total surface position information of the first side, receiving, from a second measurement device, a plurality of pieces of substrate sample thickness information indicating sample thicknesses of the substrate measured at a plurality of sampling points on the first side, and generating, based on the first side profile information and the plurality of pieces of substrate sample thickness information, a substrate thickness map including total thickness information of the substrate.

According to an aspect, a method for measuring a thickness of a substrate for a workpiece including the substrate including a first side and a second side disposed in a direction opposite to the first side, and an active structure formed on the second side may be performed by a computing device and may include receiving, from a first measurement device, first side profile information indicating a total surface position information of the first side, receiving, from the first measurement device, active structure profile information indicating total surface position information of a surface of the active structure; receiving, from a second measurement device, a plurality of pieces of substrate sample thickness information indicating sample thicknesses of the substrate measured at a plurality of sampling points on the first side, and generating, based on the first side profile information, the active structure profile information, and the plurality of pieces of substrate sample thickness information, a substrate thickness map including total thickness information of the substrate.

According to an aspect, a method for manufacturing a semiconductor device may include providing a workpiece including a substrate including a first side and a second side disposed in a direction opposite to the first side, and an active structure formed on the second side, measuring, using a first measurement device, first side profile information indicating a total surface position information of the first side, measuring, using a second measurement device, a plurality of pieces of substrate sample thickness information including sample thicknesses of the substrate measured at a plurality of sampling points on the first side, generating, using a computing device, based on the first side profile information and the plurality of pieces of substrate sample thickness information, a substrate thickness map including total thickness information of the substrate, and performing, using a substrate processing device, based on planarization target data that is set using the substrate thickness map, a planarization process on the first side.

According to various aspects of the present disclosure, even when the active structure is formed on one side of the substrate, the total thickness of the substrate can be quickly and accurately measured using the profile information and the sample substrate thickness information of that side of the substrate.

According to various aspects of the present disclosure, even when the active structure is formed on one side of the substrate, the total thickness of the substrate can be quickly and accurately measured using the profile information, the active structure profile information, and the sample substrate thickness information of that side of the substrate.

According to various aspects of the present disclosure, it is possible to quickly and accurately measure the total thickness of the substrate using the profile information of one side of the substrate and the sample substrate thickness information, or using the profile information of one side of the substrate, the active structure profile information, and the sample substrate thickness information, and provide a semiconductor device with improved integration density by using the measured values in the substrate processing process.

The effects that can be obtained through the present disclosure are not limited to those described above. Technical effects not explicitly described herein will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a block diagram provided to explain an example of a method for measuring a thickness of a substrate included in a workpiece according to some aspects;

FIG. 2 is a view provided to explain an example of a method for performing a planarization process using a substrate processing device;

FIG. 3 is a block diagram illustrating an example of a method for measuring a thickness of a substrate;

FIGS. 4 to 7 are diagrams illustrating specific examples of a process of measuring a thickness of a substrate;

FIG. 8 is a block diagram illustrating an example of a method for measuring a thickness of a substrate according to another aspect;

FIGS. 9 to 13 are diagrams illustrating specific examples of a process of measuring a thickness of a substrate;

FIG. 14 is a flowchart illustrating an example of a method for measuring a thickness of a substrate;

FIG. 15 is a flowchart illustrating an example of a method for measuring a thickness of a substrate according to another aspect;

FIG. 16 is a flowchart illustrating an example of a method for manufacturing a semiconductor device; and

FIG. 17 is a block diagram illustrating a configuration of a computing device that executes a method for measuring a thickness of a substrate according to some aspects.

### DETAILED DESCRIPTION

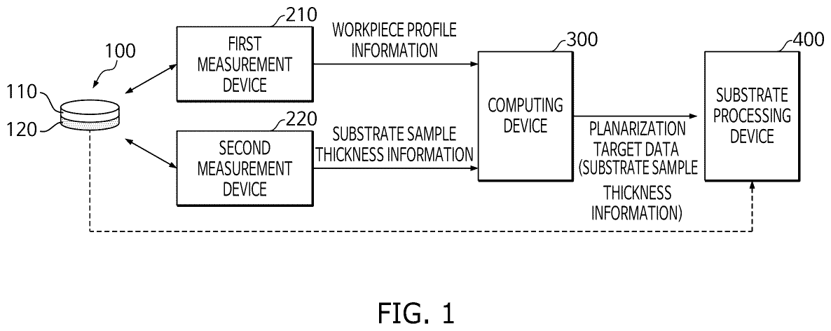

Hereinafter, various aspects of the present disclosure will be described with reference to FIGS. 1 to 17. The same reference numerals may refer to the same components throughout the description.

FIG. 1 is a block diagram provided to explain an example of a method for measuring a thickness of a substrate 110 included in a workpiece 100 according to some aspects.

A computing device 300 may use measurement information on the workpiece 100 including the substrate 110 and an active structure 120 measured by at least one of a first measurement device 210 and a second measurement device 220, to generate thickness information (substrate thickness information) of the substrate 110 included in the workpiece 100.

The substrate 110 may be a silicon substrate, or may include other materials, such as silicon germanium (SiGe), silicon germanium on insulator (SGOI), indium antimony, lead tellurium compound, indium arsenic, indium phosphide, gallium arsenic, or gallium antimony. However, aspects are not limited thereto.

The active structure 120 may be disposed on the substrate 110. The active structure 120 may represent an active component of a chip including a transistor, etc. formed on the substrate 110. In another aspect, the active structure 120 may include active components of the chip and a signal wiring component connecting the active components. In this case, one surface of the substrate 110 (e.g., a first side of the substrate) may be a surface on which a power wiring component for supplying power to the active component, etc. is disposed, and the other surface of the substrate 110 (e.g., a second side of the substrate) may be a surface on which the active structure 120 is disposed.

The substrate 110 may include the first side and the second side disposed in a direction opposite to the first side. The first side of the substrate 110 may be a surface on which the active structure is not formed. In addition, the active structure 120 may be disposed on the second side of the substrate 110. In this case, the second side of the substrate 110 may not be exposed to the outside. FIG. 1 illustrates an example of the workpiece 100 including the substrate 110 and the active structure 120, but aspects are not limited thereto. For example, the workpiece 100 may be the substrate 110 that is not formed with the active structures 120 on both surfaces thereof. For example, the substrate 110 may be a non-patterned substrate or a patterned substrate having at least one surface patterned.

The computing device 300 may receive the measurement information on the workpiece 100 from the first measurement device 210 and the second measurement device 220. The measurement information on the workpiece 100 may include shape information (e.g., surface position information) of the workpiece 100 and/or thickness information of the substrate 110 included in the workpiece 100.

The computing device 300 may receive workpiece profile information from the first measurement device 210. The first measurement device 210 may measure the shape or position information of the surface of the workpiece. For example, the first measurement device 210 may include at least one of an optical interferometer, a triangulation sensor, a confocal microscope, and a gap sensor. However, aspects are not limited thereto.

In addition, the computing device 300 may receive substrate sample thickness information from the second measurement device 220. The second measurement device 220 may measure the substrate thickness information at a plurality of sampling points with respect to the workpiece. For example, the second measurement device 220 may include at least one of an optical interferometer, a spectrometer, a spectral ellipse, and a spectral reflectometer. However, aspects are not limited thereto.

The first measurement device 210 and the second measurement device 220 may include the same device. For example, the first measurement device 210 and the second measurement device 220 may be devices including an optical interferometer. However, aspects are not limited thereto.

The computing device 300 may use the workpiece profile information received from the first measurement device 210 and the substrate sample thickness information received from the second measurement device 220 to generate a substrate thickness map including substrate thickness information. The substrate thickness map may include a vertical distance between surface position information (e.g., first side profile information) of one surface of the substrate 110 and surface position information (e.g., second side profile information) of the other surface of the substrate 110. For example, the substrate thickness map may refer to a set of vertical distance values between data points included in one surface position information and data points included in the other surface position information.

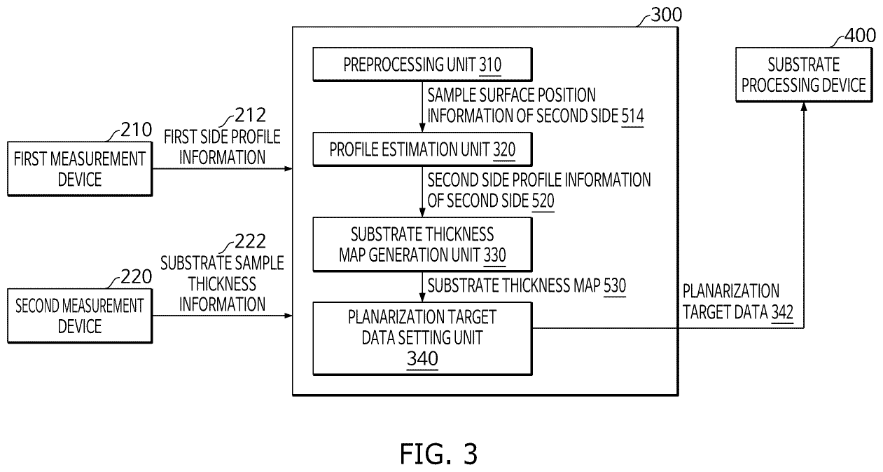

The computing device 300 may receive, from the first measurement device 210, first side profile information including total surface position information of the first side of the substrate 110. In addition, the computing device 300 may receive, from the second measurement device 220, a plurality of pieces of substrate sample thickness information including the sample thickness of the substrate 110 measured at a plurality of sampling points on the first side of the substrate 110. The computing device 300 may generate a substrate thickness map including total thickness information (substrate thickness information) of the substrate 110 based on the first side profile information and the plurality of pieces of substrate sample thickness information. A detailed method of generating the substrate thickness map based on the first side profile information and the plurality of pieces of substrate sample thickness information will be described below in detail with reference to FIGS. 3 to 7.

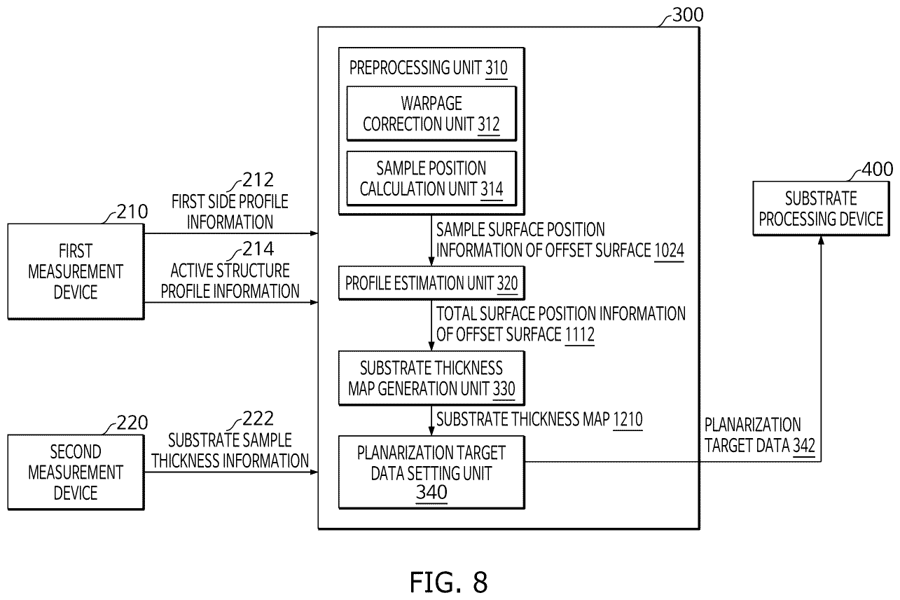

The computing device 300 may receive, from the first measurement device 210, the first side profile information indicating the total surface position information of the first side of the substrate 110. In addition, the computing device 300 may receive, from the first measurement device 210, active structure profile information indicating total surface position information of the surface of the active structure 120. In addition, the computing device 300 may receive, from the second measurement device, a plurality of pieces of substrate sample thickness information including the sample thickness of the substrate 110 measured at a plurality of sampling points on the first side of the substrate 110. The computing device 300 may generate the substrate thickness map including the total thickness information of the substrate 110 based on the first side profile information, the active structure profile information, and the plurality of pieces of substrate sample thickness information. A detailed method of generating the substrate thickness map including the total thickness information (substrate thickness information) of the substrate 110 based on the first side profile information, the active structure profile information, and the plurality of pieces of substrate sample thickness information will be described below in detail with reference to FIGS. 8 to 13.

The computing device 300 may provide a substrate processing device 400 with planarization target data including the substrate thickness information generated by using the workpiece profile information and the substrate sample thickness information. For example, the computing device 300 may use the substrate thickness information to generate the planarization target data required for the planarization process for the substrate 110 of the workpiece 100. For example, the planarization target data may include at least one of profile information of the workpiece, the substrate thickness information, target height information, substrate removal thickness information, and target total thickness variation (TTV) information. However, the element data included in the planarization target data is not limited to the example described above, and various information may be further included according to designs.

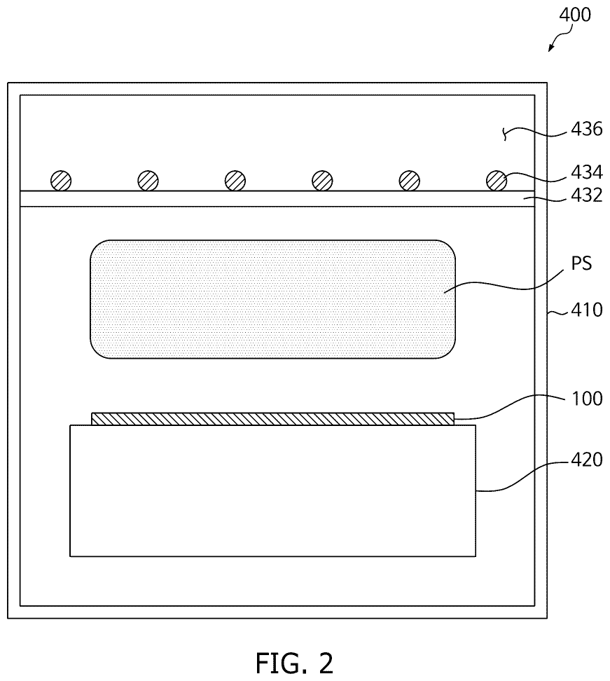

The workpiece 100 may be loaded inside the substrate processing device 400. For example, the workpiece 100 may be loaded into the substrate processing device 400 with a surface of the substrate 110, on which the active structure is not formed, facing upward. The substrate processing device 400 may perform a planarization process on the loaded workpiece 100 by using the planarization target data. For example, the substrate processing device 400 may etch or polish at least a portion of the substrate 110 by using the substrate removal thickness information or the target height information included in the planarization target data. The planarization process may include at least one of a partial planarization process, a local planarization process, and a global planarization process of a substrate. Hereinafter, the substrate processing device 400 will be described below in detail with reference to FIG. 2.

FIG. 2 is a view provided to explain an example of a method for performing a planarization process using the substrate processing device 400.

The substrate processing device 400 may perform an etching process on the substrate area of the workpiece 100 using the planarization target data received from the computing device (e.g., computing device 300 of FIG. 3). The substrate processing device 400 may include a control module that controls the etching process. The control module may use the planarization target data received from the computing device to control the substrate processing device 400 so that the substrate area of the workpiece 100 satisfies the target height or target total thickness variation. Depending on implementation requirements, the control module may be implemented as part of the computing device, or the computing device may be implemented as part of the control module.

The substrate processing device 400 may be a plasma processing device that etches the substrate area of the workpiece 100 mounted on an electrostatic chuck 420 using an inductively coupled plasma (ICP) used in inductively coupled type plasma processing devices. The electrostatic chuck 420 may also be used in the etching device using a charge-coupled plasma (CCP) used in charge-coupled type etching devices.

The substrate processing device 400 may include the electrostatic chuck 420 for mounting the workpiece 100 in a lower center of a cylindrical process chamber 410. The electrostatic chuck 420 may serve to adsorb and fix the workpiece 100. The electrostatic chuck 420 may refer to an electrostatic chuck assembly further including an electrostatic chuck controller for controlling the electrostatic chuck 420. An opening may be formed at one side of the process chamber 410 through which the workpiece 100 may be loaded into the process chamber 410 by a substrate transfer device. For example, the workpiece 100, with its shape and thickness measured with a measurement device outside the substrate processing device 400 (e.g., the first measurement device 210 and the second measurement device 220 of FIG. 1), may be loaded into the substrate processing device 400 by the substrate transfer device and mounted on the electrostatic chuck 420.

The electrostatic chuck 420 may include a base and a dielectric stack adhered to the base by an adhesive layer. The dielectric stack may include a heater dielectric layer and an electrostatic dielectric layer sequentially stacked on the base. The base may include a cooling water channel through which cooling water flows to cool the workpiece 100 in a high temperature environment inside the process chamber 410.

The base of the electrostatic chuck 420 may be electrically connected to a bias power source. High frequency or radio frequency may be applied to the base from the bias power source, and thus the base may serve as an electrode for generating plasma.

The heater dielectric layer of the electrostatic chuck 420 may include an embedded heater electrode. The heater dielectric layer may include a dielectric. The heater electrode may be a conductor and include a metal or a conductive ceramic. The heater electrode may be electrically connected to a heater power source. The heater electrode is heated by power, for example, an AC voltage from the heater power source, so that the temperature of the electrostatic chuck 420 and the workpiece 100 may be adjusted.

An embedded adsorption electrode may be installed in the electrostatic dielectric layer. The adsorption electrode may be referred to as a clamp electrode. The electrostatic dielectric layer may include a dielectric such as ceramic or polyimide. The workpiece 100 may be disposed on the electrostatic dielectric layer. The adsorption electrode may be a conductor and include a metal or a conductive ceramic.

The adsorption electrode may be electrically connected to an electrostatic chuck (ESC) power source. Electrostatic force may be generated between the adsorption electrode and the workpiece 100 by power (e.g., a direct current voltage) applied from the electrostatic chuck power source, so that the workpiece 100 may be adsorbed onto the electrostatic dielectric layer.

A dielectric window 432 spaced apart from the electrostatic chuck 420 may be disposed on a ceiling of the process chamber 410. An antenna room 436 for accommodating a high frequency antenna 434 of a coil shape such as a spiral or concentric circle may be provided integrally with the process chamber 410 on the dielectric window 432. The high frequency antenna 434 may be electrically connected to the radio frequency (RF) power source for plasma generation through an impedance matcher. The RF power source may output high frequency or radio frequency power suitable for plasma generation. The impedance matcher may be provided for matching the impedance and load of the RF power source, for example, the impedance of the high frequency antenna 434.

An etching gas may be introduced into the process chamber 410 from a gas supply source. A processing gas such as an etching gas may be supplied from the gas supply source into the process chamber 410 through a supply device such as a nozzle or a porthole disposed on one side of the process chamber 410.

The etching gas may be introduced into the process chamber 410 from the gas supply source. The processing gas, for example, the etching gas may be supplied from the gas supply source into the process chamber 410 through a supply device such as a nozzle or a porthole disposed on one side of the process chamber 410. The etching gas introduced into the process chamber 410 may be uniformly diffused into the plasma processing space formed between the dielectric window 432 and the electrostatic chuck 420.

The power from the RF power source may be applied to the high frequency antenna 434 through the impedance matcher, and the power from the bias power source may be applied to the base of the electrostatic chuck 420. A magnetic field is generated around the high frequency antenna by the current flowing through the high frequency antenna 434, and a magnetic line may pass through the dielectric window 432 and through the plasma processing space. An induced electric field may be generated according to a temporal change of the magnetic field, and electrons accelerated by the induced electric field may collide with molecules or atoms of the etching gas to generate plasma PS.

As the ions and radicals of the plasma PS are supplied to the workpiece 100, a substrate processing process, that is, a substrate etching process, may be performed in the plasma processing space.

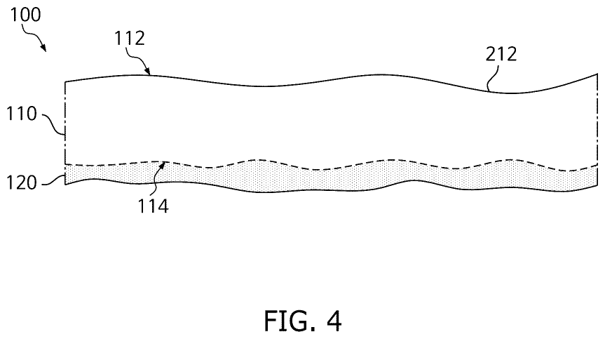

FIGS. 3 to 7 are views provided to explain a method for measuring a thickness of the substrate 110 with respect to the workpiece 100 including the substrate 110. FIG. 3 is a block diagram illustrating an example of a method for measuring a thickness of the substrate 110. FIGS. 4 to 7 are diagrams illustrating specific examples of a process of measuring the thickness of the substrate 110.

Referring to FIGS. 3 to 7, the computing device 300 may calculate the thickness of the substrate 110 with respect to the workpiece 100 including the substrate 110 that includes a first side 112 and a second side 114. The first side 112 may be a non-processed surface, that is, a surface on which the active structure 120 is not formed, and the second side 114 may be a surface on which the active structure 120 is formed. In this case, the second side 114 may hidden by the active structure 120 from exposure to the outside. In another aspect, the first side 112 and the second side 114 may be non-patterned surfaces. In yet another aspect, at least one of the first side 112 and the second side 114 may be a patterned surface. Irregularities may be formed on the first side 112 and the active structure 120 of the substrate, or warpage of the substrate 110 may occur due to the process of processing the substrate, for example, the process of forming the active structure 120 on the second side 114. As a result, the thickness of the substrate 110 (or the thickness of the workpiece 100) at each data point on the front side of the substrate 110 and the active structure 120 may not be constant.

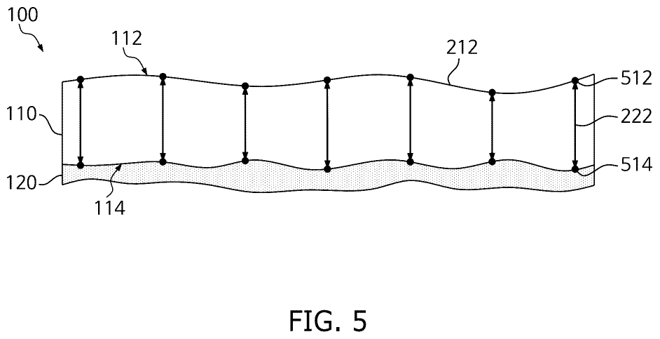

Hereinafter, for convenience of description, it will be assumed, by way of example, that the active structure 120 is disposed on the second side 114. Referring to FIGS. 4 and 5, the second side 114 is shown in dotted line to show that the surface position information is not acquired in this state.

Referring to FIG. 3, the computing device 300 may include a preprocessing unit 310, a profile estimation unit 320, a substrate thickness map generation unit 330, and a planarization target data setting unit 340. The internal configuration of the computing device 300 illustrated in FIG. 3 is merely an example and may be implemented differently in some examples. For example, the computing device 300 may further include other configurations than those illustrated, and at least part of the illustrated configurations may be omitted. In addition, FIG. 3 illustrates that the processor is divided into individual parts from a functional perspective, but this does not necessarily mean that the processor is physically separated.

Referring to FIGS. 3 and 4, the computing device 300 may receive the first side profile information 212 including the total surface position information of the first side 112 from the first measurement device 210. The received first side profile information 212 may be stored in a storage device associated with the computing device 300. The first side profile information 212 stored in the storage device may be provided to the preprocessing unit 310, the profile estimation unit 320, the substrate thickness map generation unit 330, and the planarization target data setting unit 340 as necessary.

The first side profile information 212 may indicate shape information for the first side 112 of the substrate 110. For example, the first side profile information 212 may include coordinate values of data points indicating a plurality of points of the first side 112 and a height value corresponding to the coordinates of each data point. The first side profile information 212 may be high density topography data.

Referring to FIGS. 3 and 5, the computing device 300 may receive, from the second measurement device 220, a plurality of pieces of substrate sample thickness information 222 including sample thicknesses of the substrate 110 measured at a plurality of sampling points 512 of the first side 112. The received plurality of pieces of substrate sample thickness information 222 may be stored in a storage device included in the computing device 300. The plurality of pieces of substrate sample thickness information 222 stored in the storage device may be provided to the preprocessing unit 310, the profile estimation unit 320, the substrate thickness map generation unit 330, and the planarization target data setting unit 340 as necessary. The plurality of sampling points 512 of the first side 112 may represent sampled data points on the first side 112. The substrate sample thickness information 222 may indicate the thicknesses of the substrate 110 at the plurality of sampling points 512.

Referring to FIGS. 3 and 5, the preprocessing unit 310 may calculate sample surface position information 514 of the second side 114 corresponding to the plurality of sampling points 512 of the first side 112 based on the plurality of pieces of substrate sample thickness information 222. The sample surface position information 514 of the second side 114 may indicate position information of points vertically moved from the plurality of sampling points 512 of the first side 112 by thickness values included in the sample thickness information 222. That is, the preprocessing unit 310 may determine that the positions vertically moved from the plurality of sampling points 512 of the first side 112 by the thicknesses included in the sample thickness information 222 are the sample surface position information 514 of the second side 114.

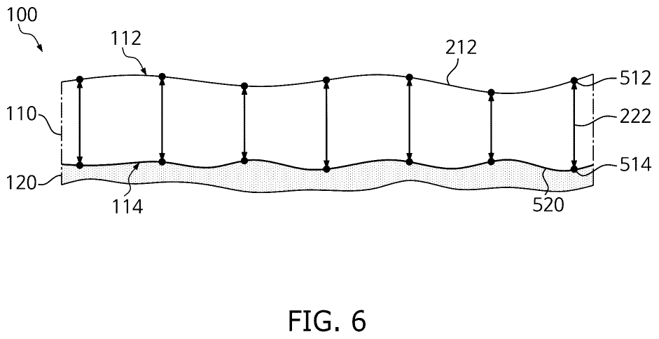

Referring to FIGS. 3 and 6, the profile estimation unit 320 may receive the sample surface position information 514 of the second side 114 from the preprocessing unit 310. The profile estimation unit 320 may determine second side profile information 520 indicating the total surface position information of the second side 114 based on the sample surface position information 514 of the second side 114. The second side profile information 520 may indicate shape information for the second side 114 of the substrate 110. The profile estimation unit 320 may generate the second side profile information 520 by estimating the total surface position information of the second side 114 using an interpolation algorithm, based on the sample surface position information 514 of the second side 114.

The interpolation algorithm may include at least one of linear interpolation, polynomial interpolation such as Lagrange interpolation and Newtonian interpolation, spline interpolation, nearest neighbor interpolation, and linear regression interpolation. However, aspects are not limited thereto.

Referring to FIG. 3, the substrate thickness map generation unit 330 may receive the second side profile information 520 from the profile estimation unit 320. In addition, the first side profile information 212 received from the first measurement device 210 may be provided to the substrate thickness map generation unit 330.

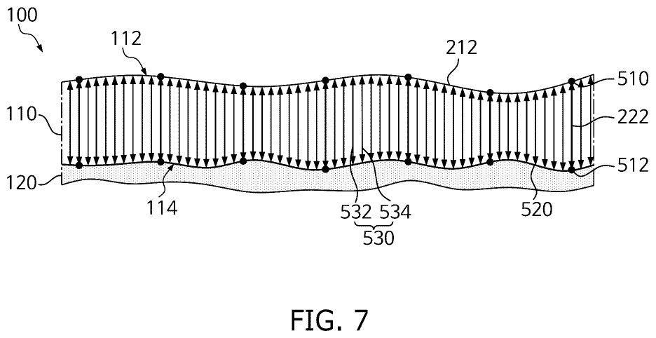

Referring to FIGS. 3 and 7, the substrate thickness map generation unit 330 may generate a substrate thickness map 530 including total thickness information 532 and 534 of the substrate based on the first side profile information 212 and the plurality of pieces of substrate sample thickness information 222. The substrate thickness map 530 may indicate the thickness of the entire substrate, which is a vertical distance between the first side profile information 212 and the second side profile information 520. For example, the substrate thickness map generation unit 330 may generate the total thickness information 532 and 534 of the substrate 110 by calculating vertical distances between the entire surface of the first side 112 and the entire surface of the second side 114 based on the total surface position information of the first side 112 included in the first side profile information 212 and the total surface position information of the second side 114 included in the second side profile information 520. The total thickness information 532 and 534 may be the vertical distances between a plurality of coordinates across the entire surface of the first side 112 and a corresponding plurality of coordinates across the entire surface of the second side 114. The plurality of coordinates across the entire surfaces of the first and second sides 112 and 114 may be a subset of all coordinates.

Referring to FIG. 3, the planarization target data setting unit 340 may receive the substrate thickness map 530 from the substrate thickness map generation unit 330. The planarization target data setting unit 340 may generate planarization target data 342 required for the planarization process for the substrate 110 based on the substrate thickness map 530. The planarization target data 342 may be provided to the substrate processing device 400 and used in the etching process with respect to the substrate 110.

Through this configuration, even when the active structure 120 is formed on the first side 112 of the substrate 110, the total thickness of the substrate may be quickly and accurately measured by using the first side profile information 212 and the substrate sample thickness information 222 of the substrate 110.

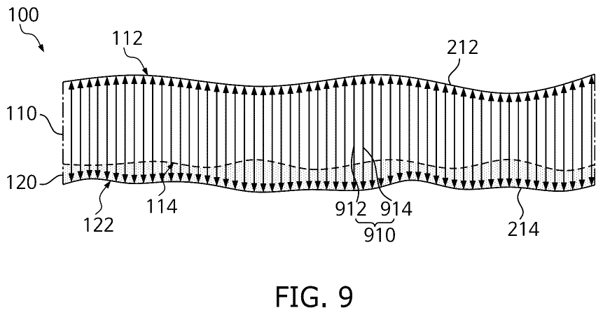

FIGS. 8 to 13 are views provided to explain a method for measuring the thickness of the substrate 110 with respect to the workpiece 100 including the substrate 110 according to another aspect. FIG. 8 is a block diagram illustrating an example of a method for measuring a thickness of the substrate 110 according to another aspect. FIGS. 9 to 13 are diagrams illustrating specific examples of a process of measuring the thickness of the substrate 110.

In describing a method for measuring a thickness of a substrate according to another aspect, the configuration already described above with reference to FIG. 3 will not be repeated or will be briefly described.

Referring to FIG. 8, the computing device 300 may include the preprocessing unit 310, the profile estimation unit 320, the substrate thickness map generation unit 330, and the planarization target data setting unit 340. The preprocessing unit 310 may include a warpage correction unit 312 and a sample position calculation unit 314. The internal configuration of the computing device 300 illustrated in FIG. 8 is merely an example and may be implemented differently in some examples. For example, the computing device 300 may further include other configurations than those illustrated, and at least part of the illustrated configurations may be omitted. In addition, FIG. 8 illustrates that the processor is divided into individual parts from a functional perspective, but this does not necessarily mean that the processor is physically separated.

The computing device 300 may further receive active structure profile information 214 indicating total surface position information of a surface 122 of the active structure 120 from the first measurement device 210. The received active structure profile information 214 may be stored in a storage device (e.g., memory) included in the computing device 300. The active structure profile information 214 stored in the storage device may be provided to the preprocessing unit 310, the profile estimation unit 320, the substrate thickness map generation unit 330, and the planarization target data setting unit 340 as necessary.

Referring to FIGS. 8 and 9, like the first side profile information 212, the active structure profile information 214 may indicate shape information for the surface 122 of the active structure 120. For example, the active structure profile information 214 may include coordinate values of data points indicating a plurality of points on the surface 122 of the active structure 120, and a height value corresponding to the coordinates of each data point. The active structure profile information 214 may be high density topography data.

The warpage correction unit 312 may generate a workpiece thickness map 910 including total thickness information 912 and 914 of the workpiece 100 based on the first side profile information 212 and the active structure profile information 214. The workpiece thickness map 910 may include total thickness information of the workpiece, which is vertical distances between the first side profile information 212 and the active structure profile information 214. For example, the warpage correction unit 312 may generate the total thickness information 912 and 914 of the workpiece 100 by calculating vertical distances between the entire surface of the first side 112 and the entire surface of the surface 122 of the active structure 120 based on the total surface position information of the first side 112 included in the first side profile information 212 and the total surface position information of the surface 122 of the active structure 120 included in the active structure profile information 214. Referring to FIG. 9, the second side 114 is shown in a dotted line to show that the surface position information is not acquired in this state.

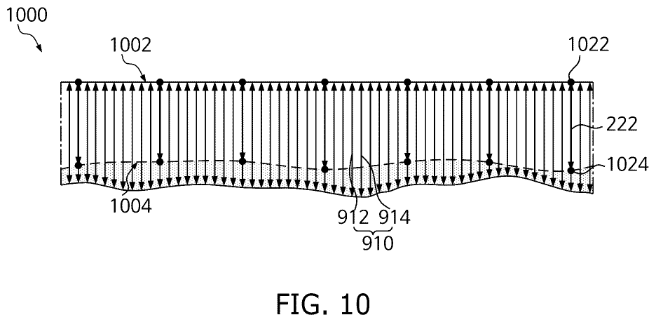

Referring to FIGS. 8 and 10, the warpage correction unit 312 may generate a warpage-corrected workpiece planarization thickness map 1000 using the workpiece thickness map 910. The workpiece planarization thickness map 1000 may be a concept including a reference surface 1002 having the same height throughout the entire surface, the workpiece thickness map 910 aligned with respect to the reference surface 1002, and an offset surface 1004 formed apart from the reference surface 1002 by the total thickness of the workpiece 100. For example, by applying the total thickness information 912 and 914 of the workpiece 100 to the reference surface 1002 that has the same height throughout the surface, the warpage-corrected workpiece planarization thickness map 1000 may be generated. In other words, the warpage-corrected workpiece planarization thickness map 1000 may be generated by aligning the workpiece thickness map 910 with respect to the reference surface 1002.

Referring to FIGS. 8 and 10, the sample position calculation unit 314 may calculate sample surface position information 1024 of the offset surface 1004 using the total thickness information 912 and 914 of the workpiece 100. The sample surface position information 1024 of the offset surface 1004 may indicate a position separated from the reference surface 1002 by a distance included in the plurality of pieces of substrate sample thickness information 222. For example, the sample position calculation unit 314 may determine a plurality of sampling points 1022 of the reference surface 1002 corresponding to the plurality of sampling points (e.g., sampling points 510 of FIGS. 5 to 7) of the first side 112 based on the plurality of pieces of substrate sample thickness information 222. The sample position calculation unit 314 may calculate the sample surface position information 1024 of the offset surface 1004 corresponding to the plurality of sampling points 1022 of the reference surface 1002.

The sampling points of the first side 112, the sampling points 1022 of the reference surface 1002, and the sample surface position information 1024 of the offset surface 1004 may each have the same coordinate value, but may indicate different height values. Referring to FIG. 10, the offset surface 1004 is shown in dotted line to show that the surface position information is not acquired in this state.

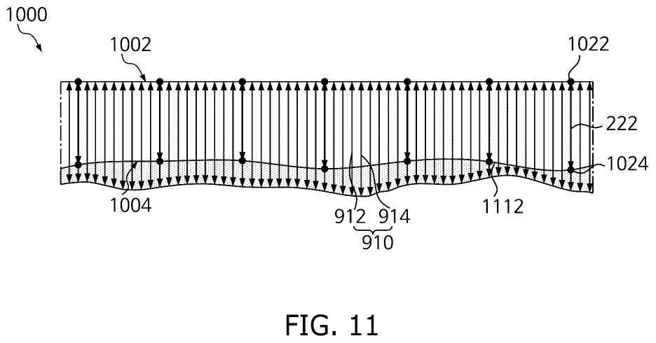

Referring to FIGS. 8 and 11, the profile estimation unit 320 may receive the sample surface position information 1024 of the offset surface 1004 from the sample position calculation unit 314 of the preprocessing unit 310. The profile estimation unit 320 may determine total surface position information 1112 of the offset surface 1004 based on the sample surface position information 1024 of the offset surface 1004. The total surface position information 1112 of the offset surface 1004 may indicate a set of respective data point positions forming the offset surface 1004. The profile estimation unit 320 may estimate the total surface position information 1112 of the offset surface 1004 using an interpolation algorithm, based on the sample surface position information 1024 of the offset surface 1004.

The interpolation algorithm may include at least one of linear interpolation, polynomial interpolation such as Lagrange interpolation and Newtonian interpolation, spline interpolation, nearest neighbor interpolation, and linear regression interpolation. However, aspects are not limited thereto.

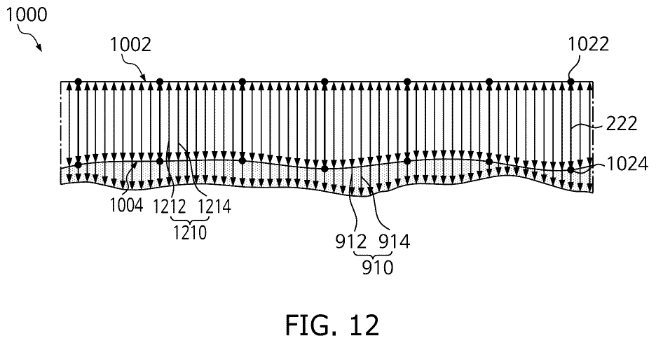

Referring to FIGS. 8 and 12, the substrate thickness map generation unit 330 may receive the total surface position information 1112 of the offset surface 1004 from the profile estimation unit 320. The substrate thickness map generation unit 330 may calculate total thickness information 1212 and 1214 of the substrate 110 based on the total surface position information of the reference surface 1002 and the total surface position information 1112 of the offset surface 1004. Each of the data points included in the total surface position information of the reference surface 1002 may have the same height value. The total thickness information 1212 and 1214 of the substrate 110 may be a vertical distance between the total surface position information of the reference surface 1002 and the total surface position information 1112 of the offset surface 1004.

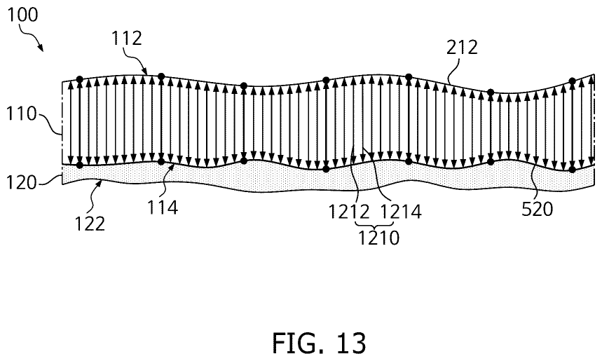

Referring to FIGS. 8 and 13, the substrate thickness map generation unit 330 may generate a substrate thickness map 1210 by calculating the second side profile information 520 using the first side profile information 212 and the total thickness information 1212 and 1214 of the substrate 110. For example, the substrate thickness map 1210 may include the thickness of the entire substrate, which is a vertical distance between the first side profile information 212 and the second side profile information 520. The substrate thickness map 1210 may be generated by converting the reference surface 1002 having the same height throughout the entire surface into the first side 112 which is a surface of the real substrate 110.

Referring to FIG. 8, the planarization target data setting unit 340 may receive the substrate thickness map 1210 from the substrate thickness map generation unit 330. The planarization target data setting unit 340 may generate planarization target data 342 required for a planarization process for the substrate 110 based on the substrate thickness map 1210. The planarization target data 342 may be provided to the substrate processing device 400 and used in an etching process with respect to the substrate 110.

Through this configuration, even if the active structure 120 is formed on the first side 112 of the substrate 110, the total thickness of the substrate may be quickly and accurately measured by using the first side profile information 212, the active structure profile information 214, and the substrate sample thickness information 222 of the substrate 110.

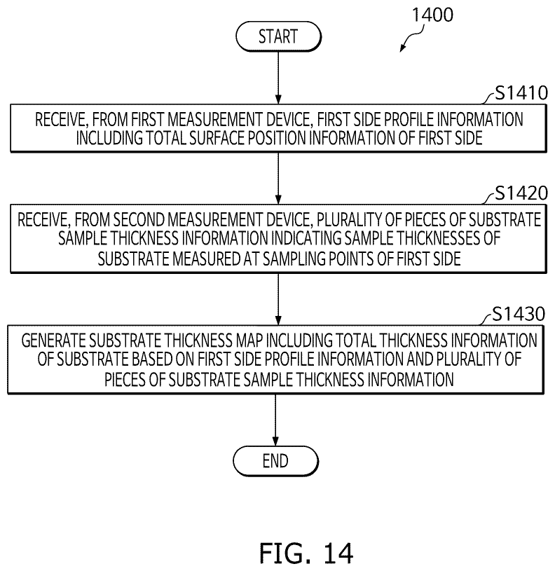

FIG. 14 is a flowchart illustrating an example of a method for measuring a thickness of a substrate 110.

The method 1400 may be a method for measuring a thickness of a substrate for a workpiece including a substrate having a first side and a second side disposed in a direction opposite to the first side. The method 1400 may be performed by a computing device (e.g., a CPU of a computing device). For example, the method 1400 may be performed by computing device 300.

The computing device may receive the first side profile information including the total surface position information of the first side from the first measurement device, at S1410. In addition, the computing device may receive, from the second measurement device, a plurality of pieces of substrate sample thickness information indicating the sample thickness of the substrate measured at the sampling point of the first side, at S1420. The computing device may generate the substrate thickness map including the total thickness information of the substrate based on the first side profile information and the plurality of pieces of substrate sample thickness information, at S1430. The generated substrate thickness map may be planarization target data and used in the etching process for the substrate of the substrate processing device.

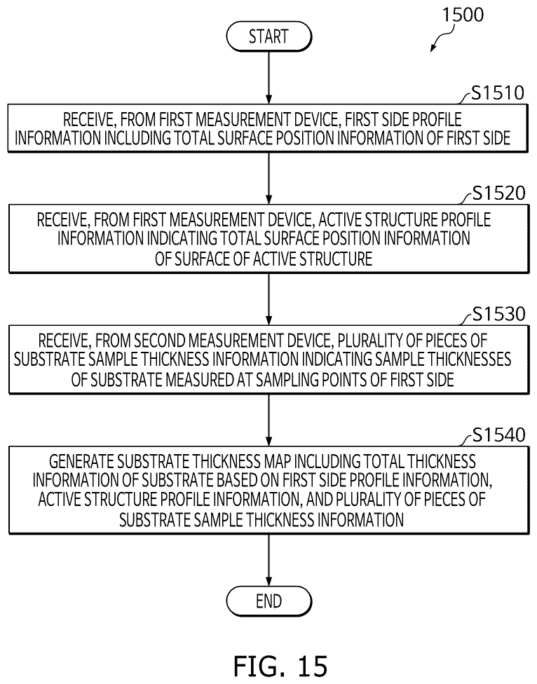

FIG. 15 is a flowchart illustrating an example of a method 1500 for measuring a thickness of a substrate according to another aspect.

The method 1500 may be a method for measuring a thickness of a substrate for a workpiece including a substrate including a first side and a second side disposed in a direction opposite to the first side, and an active structure formed on the second side. The method 1500 may be performed by a computing device (e.g., a CPU of a computing device). For example, the method 1500 may be performed by computing device 300.

The computing device may receive the first side profile information including the total surface position information of the first side from the first measurement device, at S1510. In addition, the computing device may receive, from the first measurement device, the active structure profile information indicating the total surface position information of the surface of the active structure, at S1520. In addition, the computing device may receive, from the second measurement device, a plurality of pieces of substrate sample thickness information indicating the sample thickness of the substrate measured at the sampling point of the first side, at S1530. The computing device may generate the substrate thickness map including the total thickness information of the substrate based on the first side profile information, the active structure profile information, and the plurality of pieces of substrate sample thickness information, at S1540. The generated substrate thickness map may be planarization target data and used in the etching process for the substrate of the substrate processing device.

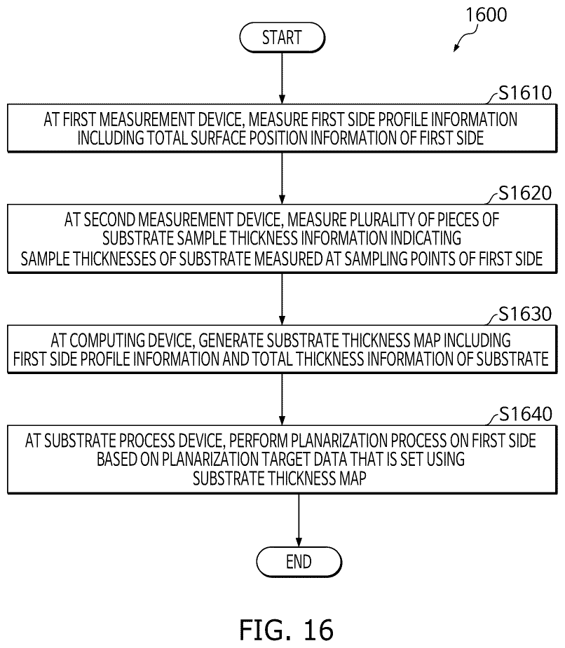

FIG. 16 is a flowchart illustrating an example of a method 1600 for manufacturing a semiconductor device.

The method 1600 may be initiated by providing a workpiece including a substrate including a first side and a second side disposed in a direction opposite to the first side, and an active structure formed on the second side, at S1610.

The first measurement device may measure the first side profile information including the total surface position information of the first side, at S1610. The second measurement device may measure a plurality of pieces of substrate sample thickness information indicating the sample thickness of the substrate measured at the sampling point of the first side, at S1620. The computing device may generate the substrate thickness map including the total thickness information of the substrate based on the first side profile information and the plurality of pieces of substrate sample thickness information, at S1630. The substrate processing device may perform planarization process on the first side of the substrate based on the planarization target data that is set using the substrate thickness map, at S1640.

After the operation S1640 is performed, the first side profile information, the substrate sample thickness information, etc. of the substrate subjected to the planarization process may be measured again by at least one of the first measurement device and the second measurement device. In addition, it is possible to determine whether the measured first side profile information, the substrate sample thickness information, etc. fall within the range of the planarization target data (e.g., target total thickness variation (TTV)). If the first side profile information, the substrate sample thickness information, etc. measured after the planarization process do not fall within the range of the planarization target data, at least one of the operations S1610 to S1640 may be repeated. For example, the computing device may regenerate the substrate thickness map including the total thickness information of the substrate, based on the re-measured first side profile information and plurality of pieces of substrate sample thickness information, at S1630. The substrate processing device may additionally perform the planarization process on the first side of the substrate based on the planarization target data that is set using the regenerated substrate thickness map, at S1640. On the other hand, if the first side profile information, the substrate sample thickness information, etc. measured after the planarization process fall within the range of the planarization target data, the method 1600 may be terminated.

The flowcharts and the description described above with reference to FIGS. 14 to 16 are merely examples, and may be implemented differently in some aspects. For example, in some examples, the order of respective operations may be changed, some of the operations may be repeatedly performed, some may be omitted, or some may be added.

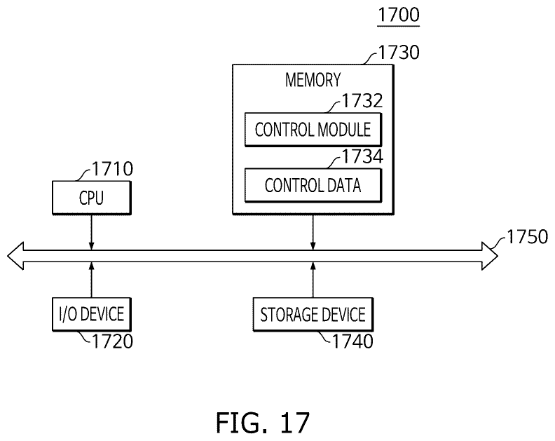

FIG. 17 is a block diagram illustrating a configuration of a computing device 1700 that executes a method for measuring a thickness of a substrate according to some aspects.

FIG. 17 is a block diagram of the computing device 1700. The computing device 1700 may include a CPU 1710, a memory 1730, an input/output (I/O) device 1720, a storage device 1740, and a bus 1750 that allows communication among the CPU 1710, the memory 1730, the input/output (I/O) device 1720, and the storage device 1740. The computing device 1700 of FIG. 17 may correspond to the computing device 300 of FIGS. 1, 3, and 8.

The CPU 1710 may execute software (e.g., applications including programs for executing the method for measuring the thickness of the substrate and the method for controlling etching process in the substrate processing device, operating systems, and device drivers) to be performed on the computing device 1700. The CPU 1710 may process data or output a control signal according to a program stored in the memory 1730.

The memory 1730 may be a volatile memory such as a static random access memory (SRAM) or a dynamic random access memory (DRAM), or a non-volatile memory such as PRAM, MRAM, ReRAM, FRAM, NOR flash memory, etc.

The memory 1730 may include control modules 1732 including a program code for executing the method for measuring a thickness and the method for controlling etching process in the substrate processing device, and control data 1734 referenced by the control module 1732 and including measurement information on the workpiece including the substrate, target height information, substrate removal thickness information, target total thickness variation, etc.

The input/output (I/O) device 1720 controls user input and output to and from a user interface. For example, it may include an input interface for the user to set the target height of the substrate, and an output interface for outputting data such as the surface shape and thickness of a workpiece including a substrate.

The storage device 1740 is provided as storage medium of a computing device 1300. The storage device 1740 may store various data such as measurement information received from the measurement device (e.g., 210 or 220 of FIG. 1). The storage device 1740 may be provided as a memory card (MMC, eMMC, SD, MicroSD, etc.) or a hard disk drive (HDD). The storage device 1740 may include a NAND-type flash memory having a large storage capability. Alternatively, the storage device 1740 may include a next-generation non-volatile memory such as PRAM, MRAM, ReRAM, FRAM, or a NOR flash memory.

The units of computing device 1700 (e.g., preprocessing unit 310, warpage correction unit 312, sample position calculation unit 314, profile estimation unit 320, substrate thickness map generation unit 330, and planarization target data setting unit 340) may each correspond to a separate segment or segments of software (e.g., a subroutine) which configure the computing device 1700, and/or may correspond to segment(s) of software that also correspond to one or more other units described herein (e.g., the units may share certain segment(s) of software or be embodied by the same segment(s) of software).

In addition, computing device 1700 may include antennas, network interfaces that provide wireless and/or wire line digital and/or analog interface to one or more networks over one or more network connections (not shown), and a power source that provides an appropriate alternating current (AC) or direct current (DC) to power one or more components of computing device 1700.

Although the present disclosure has been described above by way of certain aspects and drawings, the present disclosure is not limited thereto, and it goes without saying that various changes and modifications can be made within the equivalent scope of the technical idea of the present disclosure and the claims to be described below by those of ordinary skill in the art.

1. A method for measuring a thickness of a substrate for a workpiece including the substrate having a first side and a second side disposed in a direction opposite to the first side, the method being performed by a computing device and comprising:
receiving, from a first measurement device, first side profile information including total surface position information of the first side;
receiving, from a second measurement device, a plurality of pieces of substrate sample thickness information indicating sample thicknesses of the substrate measured at a plurality of sampling points on the first side; and
generating, based on the first side profile information and the plurality of pieces of substrate sample thickness information, a substrate thickness map including total thickness information of the substrate.

2. The method according to claim 1, wherein the generating the substrate thickness map includes:
calculating, based on the plurality of pieces of substrate sample thickness information, sample surface position information of the second side corresponding to the plurality of sampling points of the first side;
determining, based on the sample surface position information of the second side, second side profile information indicating total surface position information of the second side; and
calculating, based on the first side profile information and the second side profile information, the total thickness information of the substrate.

3. The method according to claim 2, wherein the determining the second side profile information includes estimating, based on the sample surface position information of the second side, the total surface position information of the second side using an interpolation algorithm.

4. The method according to claim 2, wherein the calculating the total thickness information of the substrate based on the first side profile information and the second side profile information includes:
calculating the total thickness information of the substrate by calculating, based on the total surface position information of the first side included in the first side profile information, a vertical distance between the entire surface of the first side and the entire surface of the second side and the total surface position information of the second side included in the second side profile information.

5. The method according to claim 1, wherein the first measurement device is a device that acquires the first side profile information of the first side using at least one of an optical interferometer, a triangulation sensor, a confocal microscope, and a gap sensor.

6. The method according to claim 1, wherein the second measurement device is a device that acquires the plurality of pieces of substrate sample thickness information using at least one of an optical interferometer, a spectrometer, a spectroscopic ellipsometry, and a spectral reflectometer.

7. The method according to claim 1, wherein the first side and the second side are surfaces on which an active structure is not formed.

8. The method according to claim 1,
wherein the first side is a surface on which an active structure is not formed, and
wherein the active structure is formed on the second side.

9. A method for measuring a thickness of a substrate for a workpiece including the substrate including a first side and a second side disposed in a direction opposite to the first side, and an active structure formed on the second side, the method being performed by a computing device and comprising:
receiving, from a first measurement device, first side profile information indicating total surface position information of the first side;
receiving, from the first measurement device, active structure profile information indicating total surface position information of a surface of the active structure;
receiving, from a second measurement device, a plurality of pieces of substrate sample thickness information indicating sample thicknesses of the substrate measured at a plurality of sampling points on the first side; and
generating, based on the first side profile information, the active structure profile information, and the plurality of pieces of substrate sample thickness information, a substrate thickness map including total thickness information of the substrate.

10. The method according to claim 9, wherein the generating the substrate thickness map includes:
calculating, based on the first side profile information and the active structure profile information, total thickness information of the workpiece; and
calculating, based on the total thickness information of the workpiece and the plurality of pieces of substrate sample thickness information, the total thickness information of the substrate.

11. The method according to claim 10, wherein the calculating the total thickness information of the workpiece includes:
calculating the total thickness information of the workpiece by calculating, based on the total surface position information of the first side included in the first side profile information and the total surface position information of the surface of the active structure included in the active structure profile information, a vertical distance between the entire surface of the first side and the entire surface of the active structure.

12. The method according to claim 10, wherein the calculating, based on the total thickness information of the workpiece and the plurality of pieces of substrate sample thickness information, the total thickness information of the substrate includes:
generating, by applying the total thickness information of the workpiece to a reference surface, a warpage-corrected workpiece planarization thickness map;
calculating sample surface position information of an offset surface separated from the reference surface by a distance included in the plurality of pieces of substrate sample thickness information;
determining, based on the sample surface position information of the offset surface, total surface position information of the offset surface; and
calculating, based on total surface position information of the reference surface and the total surface position information of the offset surface, the total thickness information of the substrate.

13. The method according to claim 12, wherein the calculating the sample surface position information of the offset surface includes:
determining, based on the plurality of pieces of substrate sample thickness information, a plurality of sampling points of the reference surface corresponding to the plurality of sampling points of the first side; and
calculating the sample surface position information of the offset surface corresponding to the plurality of sampling points of the reference surface.

14. The method according to claim 12, wherein the determining the total surface position information of the offset surface includes:
estimating, using an interpolation algorithm, based on the sample surface position information of the offset surface, the total surface position information of the offset surface.

15. The method according to claim 9, wherein the generating the substrate thickness map further includes:
calculating, by applying the total thickness information of the substrate to the first side profile information, second side profile information.

16. The method according to claim 9, wherein the first measurement device is a device that acquires the first side profile information using at least one of an optical interferometer, a triangulation sensor, a confocal microscope, and a gap sensor.

17. The method according to claim 9, wherein the second measurement device is a device that acquires the plurality of pieces of substrate sample thickness information using at least one of an optical interferometer, a spectrometer, a spectroscopic ellipsometry, and a spectral reflectometer.

18. The method according to claim 9, wherein the first side is a surface on which an active structure is not formed.

19. A method for manufacturing a semiconductor device, comprising:
providing a workpiece including a substrate including a first side and a second side disposed in a direction opposite to the first side, and an active structure formed on the second side;
measuring, using a first measurement device, first side profile information indicating a total surface position information of the first side;
measuring, using a second measurement device, a plurality of pieces of substrate sample thickness information including sample thicknesses of the substrate measured at a plurality of sampling points on the first side;
generating, using a computing device, based on the first side profile information and the plurality of pieces of substrate sample thickness information, a substrate thickness map including total thickness information of the substrate; and
performing, using a substrate processing device, based on planarization target data that is set using the substrate thickness map, a planarization process on the first side.

20. The method according to claim 19, wherein the generating the substrate thickness map further includes:
calculating, based on the plurality of pieces of substrate sample thickness information, sample surface position information of the second side corresponding to the plurality of sampling points of the first side;
determining, using an interpolation algorithm, based on the first side profile information and the sample surface position information of the second side, second side profile information by estimating total surface position information of the second side; and
calculating, based on the first side profile information and the second side profile information, the total thickness information of the substrate.
